(19) United States
(12) Patent Application Publication
(10) Pub. No.: US 2013/0035881 A1
(43) Pub. Date: Feb. 7, 2013

(54) METHOD AND SYSTEM FOR CHARACTERIZING EFFICIENCY IMPACT OF INTERRUPTION DEFECTS IN PHOTOVOLTAIC CELLS

(71) Applicants: Choon (George) Hoong Hoo, Singapore (SG); Patrick Tung-Sing Pak, Singapore (SG); Choon Wai Chang, Singapore (SG); Kristiaan Van Rossen, Bierbeek (BE); Johan DeGreeve, Brabant (BE); Lieve Govaerts, Heverlee (BE); Jia-Jie Patrick Yin, Shanghai (CN)

(72) Inventors: Choon (George) Hoong Hoo, Singapore (SG); Patrick Tung-Sing Pak, Singapore (SG); Choon Wai Chang, Singapore (SG); Kristiaan Van Rossen, Bierbeek (BE); Johan DeGreeve, Brabant (BE); Lieve Govaerts, Heverlee (BE); Jia-Jie Patrick Yin, Shanghai (CN)

(73) Assignee: KLA-TENCOR CORPORATION, Milpitas, CA (US)

(21) Appl. No.: 13/565,183

(22) Filed: Aug. 2, 2012

Related U.S. Application Data
(60) Provisional application No. 61/515,546, filed on Aug. 5, 2011.

(51) Int. Cl. G01R 31/327; G06F 19/00

(52) U.S. Cl. 702/58

(57) ABSTRACT

A system for characterizing interruption defect induced efficiency loss in a photovoltaic cell includes an inspection system configured to acquire inspection data from a photovoltaic cell, a control system configured to: receive the inspection data acquired from the photovoltaic cell, identify one or more interruption defects in one or more fingers of an electrode of the one photovoltaic cell utilizing the inspection data, determine a spatial parameter associated with at least one of the identified interruption defects and one or more floating finger portions of the one or more fingers created by two or more identified interruption defects, determine an interruption-defect-induced efficiency loss of the photovoltaic cell based on the determined spatial parameter associated with the at least one of the identified interruption defects and the floating finger portions of the one or more fingers created by two or more identified interruption defects.

### CROSS-REFERENCE TO RELATED APPLICATION

The present application is related to and claims the benefit of the earliest available effective filing date(s) from the following listed application(s) (the “Related Applications”) (e.g., claims earliest available priority dates for other than provisional patent applications or claims benefits under 35 USC §119(e) for provisional patent applications, for any and all parent, grandparent, great-grandparent, etc. applications of the Related Application(s)).

### RELATED APPLICATIONS

For purposes of the USPTO extra-statutory requirements, the present application constitutes a regular (non-provisional) patent application of United States Provisional Patent Application entitled INSPECTION METHOD FOR SOLAR CELLS, naming Choon (George) Hoong Hoo, Kristiaan Van Rossen, Johan De Greeve, and Lieve Govaerts as an inventor, filed Aug. 5, 2011 Application Ser. No. 61/515,546.

### TECHNICAL FIELD

The present invention generally relates to the determination of efficiency losses created by interruption defects in photovoltaic cells, and, in particular, to the estimation of efficiency losses in photovoltaic cells utilizing various spatial parameters associated with identified interruption defects in the photovoltaic cells.

### BACKGROUND

As the demand for cheaper and higher-performance photovoltaic cells continues to increase, so too will the need for improved efficiencies in photovoltaic cells. During fabrication of photovoltaic cells yield management systems closely monitor the production process of photovoltaic cells in order to identify sub-standard photovoltaic cells as well as correcting processing standards of the process line in order to reduce or eliminate observed deficiencies. One defect that may lead to a reduction in efficiency of a photovoltaic cell is that of an interruption defect, which consists of a gap in one or more line fingers spanning a pair of adjacent bus bars, which together may form the front-side electrical contact structure used for collection of electrons from the underlying semiconductor junction. Currently, inspection systems are commonly implemented in order to identify interruption defects in the line fingers of the electrode structure of photovoltaic cells. Utilizing the inspection data from the inspection systems an analysis system may estimate an efficiency impact on the analyzed device by counting the number of interruption defects present in the line fingers of the photovoltaic cell. Mere counting of the number of interruption defects in a photovoltaic cell or a portion of a photovoltaic cell may lead to an incorrect characterization or “rating” of the efficiency loss of the measured photovoltaic cells. As such, it would be desirable to provide a method and system that overcomes the deficiencies of the prior art.

### SUMMARY

A system for characterizing efficiency impact caused by one or more interruption defects of one or more photovoltaic cells is disclosed. In one aspect, the system may include, but is not limited to, one or more inspection systems configured to acquire one or more sets of inspection data from at least a portion of at least one photovoltaic cell; a computer control system communicatively coupled to the one or more inspection systems and configured to: receive the one or more inspection data sets acquired from the at least a portion of the at least one photovoltaic cell; identify one or more interruption defects in one or more fingers of at least one electrode of the at least one photovoltaic cell utilizing the one or more inspection data sets; determine one or more spatial parameters associated with at least one of the one or more identified interruption defects and one or more floating finger portions of the one or more fingers created by two or more identified interruption defects; determine an interruption-defect-induced efficiency loss of the at least one photovoltaic cell based on the determined one or more spatial parameters associated with the at least one of the one or more identified interruption defects and the one or more floating finger portions of the one or more fingers created by two or more identified interruption defects.

A system for characterizing efficiency impact caused by one or more interruption defects of one or more photovoltaic cells is disclosed. In one aspect, the system may include, but is not limited to, one or more inspection systems configured to acquire one or more sets of inspection data from at least a portion of at least one photovoltaic cell; a computer control system communicatively coupled to the one or more inspection systems and configured to: receive one or more inspection data sets acquired from the at least a portion of the at least one photovoltaic cell; identify one or more interruption defects in one or more fingers of at least one electrode of the at least one photovoltaic cell utilizing the one or more inspection data sets; determine one or more spatial parameters associated with at least one of the one or more identified interruption defects; and generate an interruption criticality index value indicative of interruption-defect-induced efficiency loss of the at least one photovoltaic cell utilizing the determined one or more spatial parameters associated with the at least one of the one or more identified interruption defects of the at least one photovoltaic cell.

A method for characterizing efficiency impact caused by one or more interruption defects of one or more photovoltaic cells is disclosed. In one aspect, the method may include, but is not limited to, receiving one or more inspection data sets acquired from the at least a portion of the at least one photovoltaic cell; identifying one or more interruption defects in one or more fingers of at least one electrode of the at least one photovoltaic cell utilizing the one or more inspection data sets; determining one or more spatial parameters associated with at least one of the one or more identified interruption defects; and determining an interruption-defect-induced efficiency loss of the at least one photovoltaic cell based on the determined one or more spatial parameters associated with the at least one of the one or more identified interruption defects and the one or more floating finger portions of the one or more fingers created by two or more identified interruption defects.

A method for characterizing efficiency impact caused by one or more interruption defects of one or more photovoltaic cells is disclosed. In one aspect, the method may include, but is not limited to, receiving one or more inspection data sets acquired from the at least a portion of the at least one photovoltaic cell; identifying one or more interruption defects in one or more fingers of at least one electrode of the at least one photovoltaic cell utilizing the one or more inspection data sets; determining one or more spatial parameters associated with at least one of the one or more identified interruption defects; and generating an interruption criticality index value indicative of interruption-defect-induced efficiency loss of the at least one photovoltaic cell utilizing the determined one or more spatial parameters associated with the at least one of the one or more identified interruption defects of the at least one photovoltaic cell.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF THE DRAWINGS

The numerous advantages of the disclosure may be better understood by those skilled in the art by reference to the accompanying figures in which:

FIG. 1A is a schematic top view of a portion of a photovoltaic cell, in accordance with one embodiment of the present invention.

FIG. 1B is a schematic glancing angle view of a portion of a photovoltaic cell, in accordance with one embodiment of the present invention.

FIG. 1C is a block diagram view of a portion of a photovoltaic cell depicting interruption defects, in accordance with the present invention.

FIG. 1D is a block diagram view of a portion of a photovoltaic cell depicting interruption defects, in accordance with the present invention.

FIG. 1E is a block diagram view of a portion of a photovoltaic cell depicting interruption defects, in accordance with the present invention.

FIG. 1F is a block diagram view of a portion of a photovoltaic cell depicting interruption defects, in accordance with the present invention.

FIG. 1G is a block diagram view of a portion of a photovoltaic cell depicting the quantification of the size and position of an interruption defect, in accordance with the present invention.

FIG. 1H is a block diagram view of a portion of a photovoltaic cell depicting the quantification of the size of an interruption defect and the size of a floating finger section, in accordance with the present invention.

FIG. 1I is a block diagram view of a portion of a photovoltaic cell depicting the quantification of the size and position of an interruption defect and a floating finger section, in accordance with the present invention.

FIG. 2A is a block diagram view of a system for characterizing efficiency impact caused by one or more interruption defects of one or more photovoltaic cells, in accordance with the present invention.

FIG. 2B-2G are block diagram views of various interrupt defect configurations, in accordance with the present invention.

FIGS. 3A-3B are schematic views of photovoltaic cells having multiple interrupt defects characterizable using an interruption criticality index (ICI), in accordance with the present invention.

FIG. 4 is a flow chart illustrating a method for characterizing efficiency impact caused by one or more interruption defects of one or more photovoltaic cells, in accordance with the present invention.

FIG. 5 is a flow chart illustrating a method for characterizing efficiency impact caused by one or more interruption defects of one or more photovoltaic cells, in accordance with the present invention.

### DETAILED DESCRIPTION OF THE INVENTION

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention. Reference will now be made in detail to the subject matter disclosed, which is illustrated in the accompanying drawings.

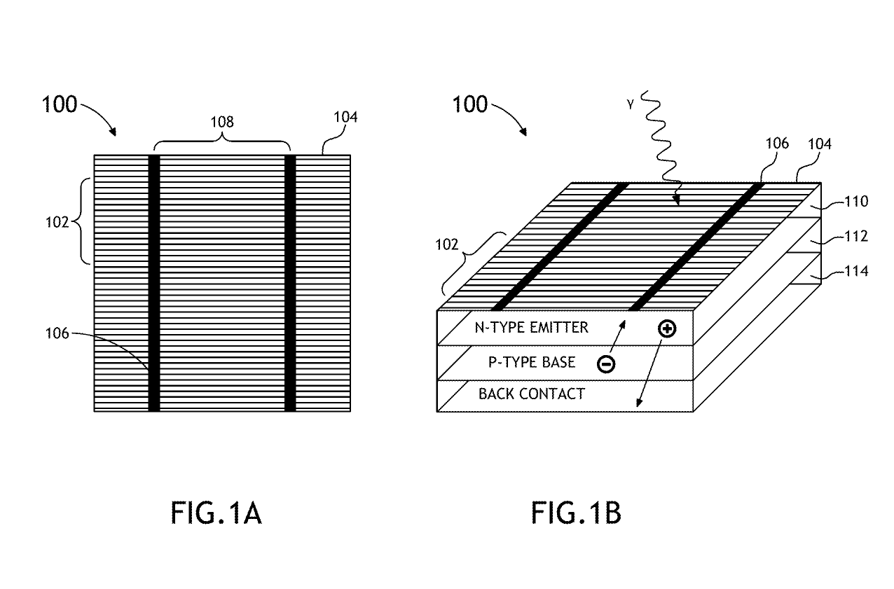

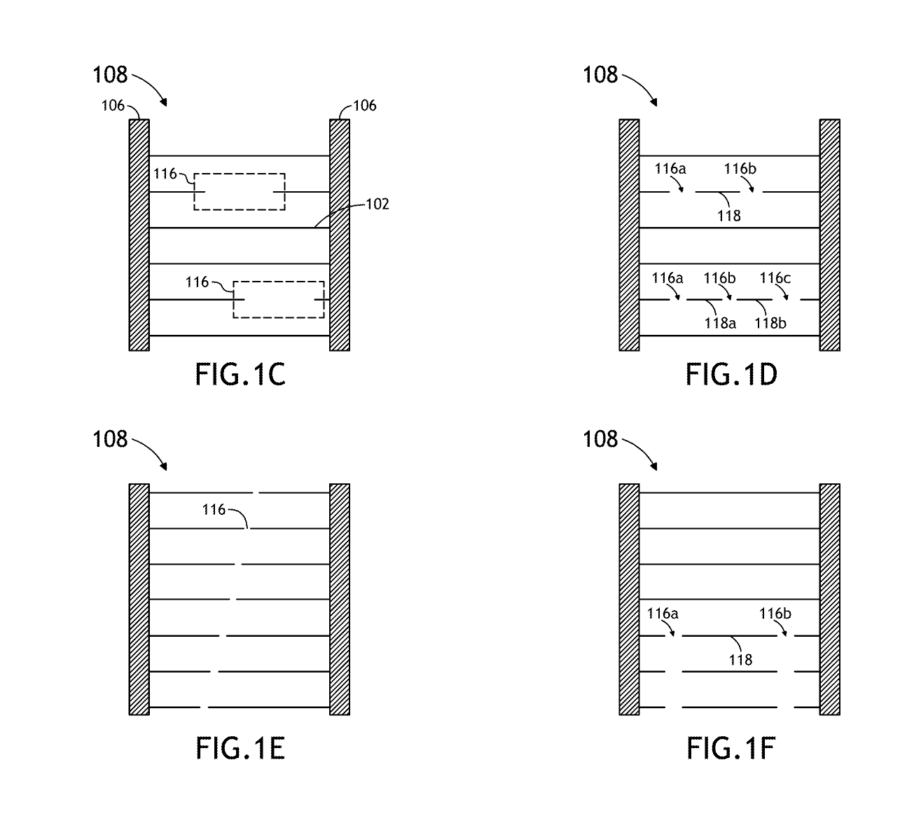

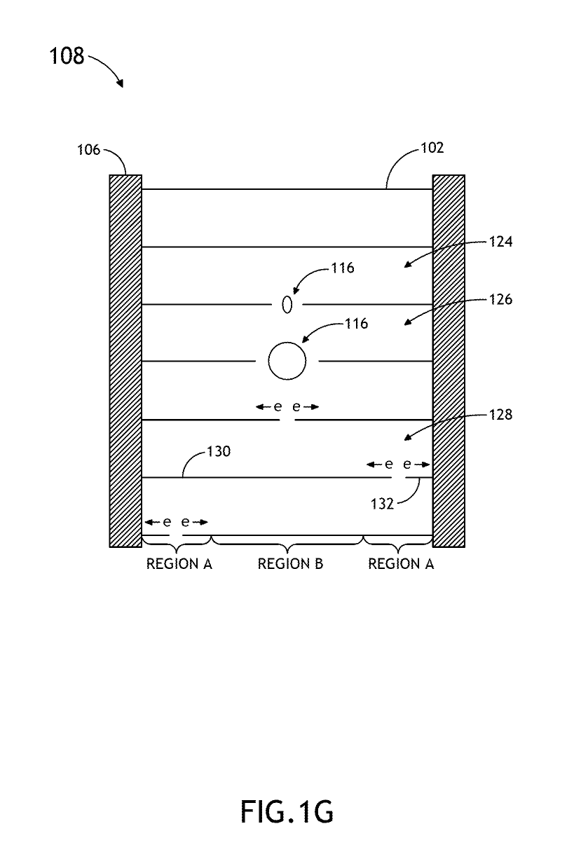

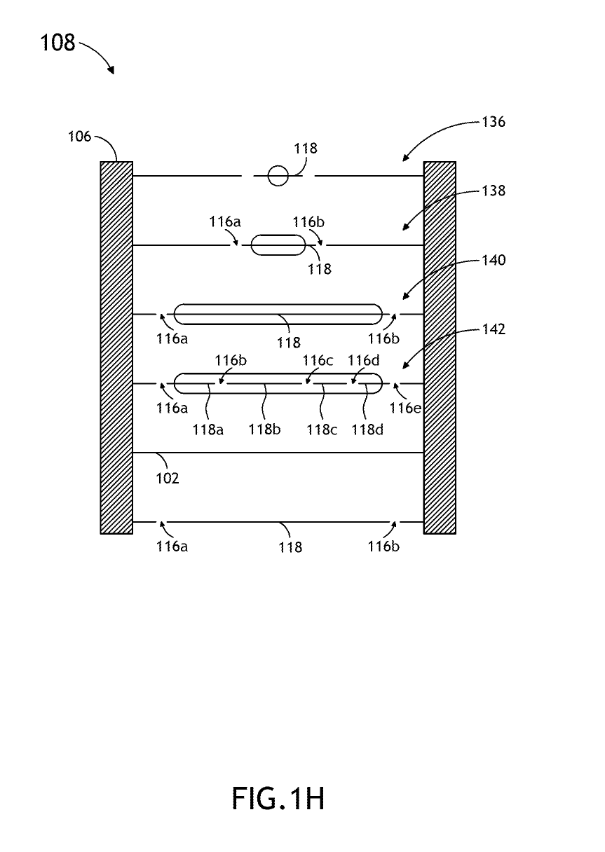

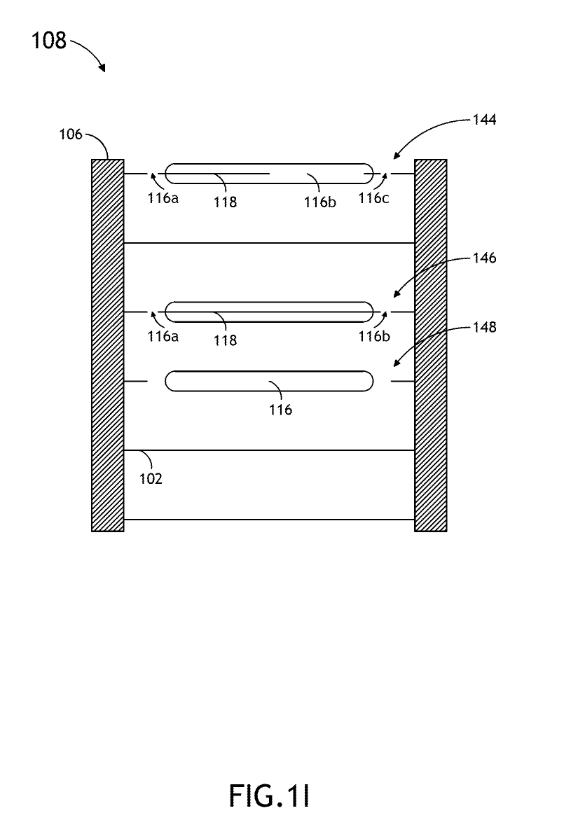

Referring generally to FIG. 1A through 3B, systems and methods for characterizing efficiency impact caused by one or more interruption defects of one or more photovoltaic cells is described in accordance with the present disclosure. The present invention is directed to a system and method for estimating the impact one or more interruption defects present in the fingers of a photovoltaic cell electrode have on the efficiency of the one or more photovoltaic cells. The present invention allows a user to more accurately determine the expected efficiency of a given photovoltaic cell utilizing inspection data acquired from the photovoltaic cell.

FIGS. 1A-1B illustrate schematic views of a photovoltaic cell 100, in accordance with the present invention. The photovoltaic cell (e.g., solar cell) consists of a semiconductor junction that generates electron-hole pairs when placed under illumination, with electrons generated in the p-type base 112 and holes generated in the n-type emitter 110. Those skilled in the art should recognize that these generated electron-hole pairs result in a net electric current across the photovoltaic device when the device is exposed to illumination. In order to harness the generated electrical current, front 104 and back electrical contacts 114 must be deposited on the front and back side of the device 100. In a general sense, the electrical contacts are generally formed of a non-transparent metal (e.g., not transparent to visible light), requiring a minimization of the surface area of the front-side contact (i.e., side facing illumination source (e.g., Sun)) in order to maximize the amount of illumination absorbed by the underlying semiconductor junction. Further, the front-side contact must also be large enough to adequately collect and transport electrons from the underlying junction. The front-side contact may include a plurality of bus bars 106 and a plurality of fingers 102 (i.e., line fingers) which act to transport collected electrons from the underlying junction to the bus bars 106 which in turn transport the electrons to the given external circuitry. In order to increase the photovoltaic cell 100 efficiency, the fingers 102 are generally fabricated to be as thin as possible, thereby covering as little surface area of the underlying junction as possible. As a result of this drive to minimize the thickness of the fingers 102 of the cell 100, interruption defects (see FIGS. 1C-1F) may develop in one or more fingers 102.

It is further contemplated that the back side contact 114 may include multiple line fingers (not shown) as well. As such, the present invention should be interpreted to extend to settings where a given photovoltaic cell includes multiple back side contact fingers for collecting charged particles. The concepts described herein are equally applicable to a backside finger setting.

FIGS. 1C and 1D illustrate top schematic views of local regions 108 of line fingers 102 having one or more interrupt defects 116 located between two bus bars 106 of a photovoltaic cells 100. As shown in FIG. 1C, an interrupt defect 116 includes a gap or a lack of electrical continuity along a line finger 102 between two bus bars 106. It should be recognized that this interruption defect 116 leads to a loss in efficiency of the photovoltaic cell 100 because fewer electrons are collected from the underlying semiconductor junction. In addition, as shown in FIG. 1D, the presence of two or more interrupt defects (e.g., 116a-116b or 116a-116c) leads to the development of a floating finger section 118, consisting of a region of the line finger 102 that is electrically isolated from the remainder of the finger 102 as well as the bus bars 106. In the same way, the existence of an interruption defect 116 leads to loss of efficiency in the photovoltaic cell 100 so too does the presence of one or more floating finger sections 118.

FIGS. 1E and 1F illustrate top schematic views of a local region of line fingers having an arrangement of interrupt defects 116 that may lead to incorrect classification by currently existing efficiency classification schemes. Currently implemented methods for characterizing the impact on efficiency caused by these interruption defects fail to consider the position, configuration, or size of the one or more interrupt defects 116 in a given photovoltaic cell 100. Commonly implemented classification schemes merely “count” the number of interruption defects 116 in a given photovoltaic cell or a portion 108 of a photovoltaic cell 100 in order to estimate the efficiency impact caused by the interrupt defects 116. Due to this shortcoming, current methods may wrongly classify an analyzed photovoltaic cell 100. FIG. 1E depicts a series of seven interruption defects 116, each being located relatively close to a center position of the line fingers 102. FIG. 1F depicts a series of six interruption defects 116, with each of the both three fingers 102 including two interruption defects 116a, 116b. The pairs of interruption defects 116a, 116b created a floating finger section 118 in each of the bottom three fingers 102 of FIG. 1F, whereby each of the floating finger sections 118 is electrically isolated from the bus bars 106. In contrast, although some small amount of collection ability has been lost due to the size of the defects 116 in FIG. 1E, the vast majority of each of the fingers 102 remains in electrical communication with the bus bars 106. As such, the portion 108 of the cell 100 of FIG. 1E should possess an efficiency larger than that found in FIG. 1F. However, current methods relying on mere defect counting would indicate that the cell 100 of FIG. 1F possesses a larger efficiency than the cell 100 of FIG. 1E.

FIGS. 1G-1I illustrate top schematic views of portions 108 of a photovoltaic cell 100 containing various types of interruption defect 116 configurations. Configurations 124 and 126 of FIG. 1G depict a small interruption defect 116 and a large interruption defect 116, whereby the ability of a finger 102 to collect electrons from the underlying junction is inversely related to the size of the interruption defect 116. Configuration 128 depicts an interruption defect 116 located at a non-centered position of the corresponding finger 102. The location of an interruption defect 116 at a non-centered position leads to a resistive loss, wherein the longer portion 130 of the finger 102 is more resistive to electron flow than is the shorter path 132. This phenomenon forces a portion of the electrons to flow a farther distance than had the defect 116 been located at the center, which, in turn, creates an increased resistive loss term measured relative to the resistive loss that exists in a centered configuration.

As shown in FIG. 1H, the presence of two or more interruption defects leads to the existence of one or more floating finger sections 118. For example, as shown in configuration 136, 138 and 140, the present of two interruption defects 116a, 116b gives rise to the floating finger section 118. In a general sense, the amount of collection efficiency loss caused by a given floating finger section 118 is directly related to the length of the floating finger section 118. In this regard, the section 118 of configuration 136 will have a smaller collection loss than configuration 138 and 140, while configuration 138 will have a smaller collection loss than 140. Further, configuration 142 depicts the creation of four floating finger sections 118a-118d via that presence of five interruption defects 116a-116e. In a further aspect, it is recognized that the amount of collection loss of a series of floating finger sections (e.g., 118a-118d of configuration 142) may approximately be equal to the collection loss associated with a single floating section (e.g., 118 of configuration 140) of the same length as the combined length of the series of floating finger sections.

As shown in FIG. 1I, interruption defects, floating finger sections, and combination thereof having the same spatial may have the same or nearly the same impact on collection-based efficiency loss. For example, configuration 144 includes a combination of a floating finger section 118 and an interruption defect 116b, configuration 146 includes a single large floating finger section 118, and configuration 148 includes a single large interruption defect 116. Each of the above configurations possesses a substantially similar length. As such, each configuration experiences approximately the same collection-based efficiency loss.

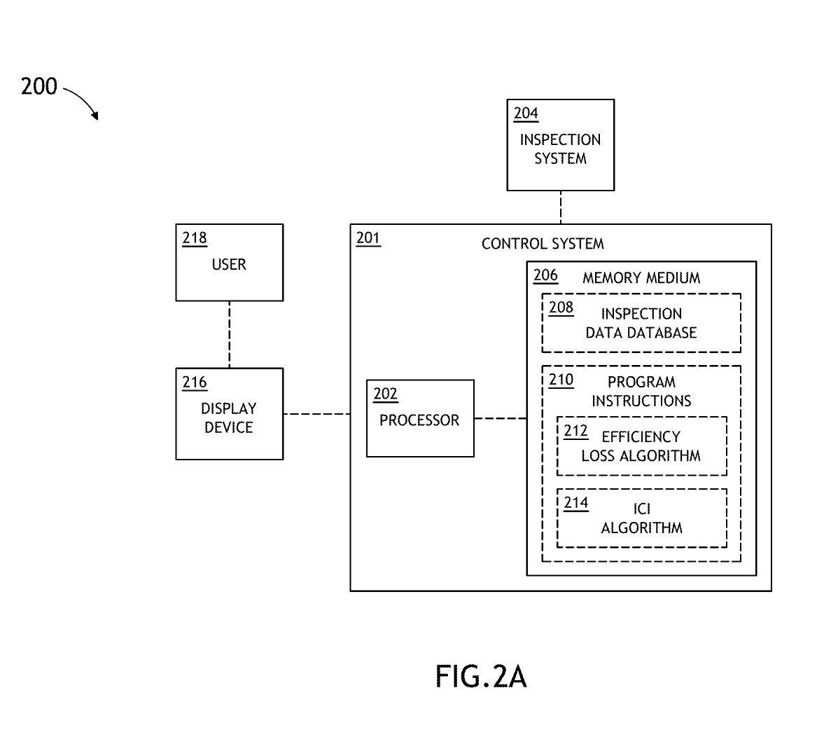

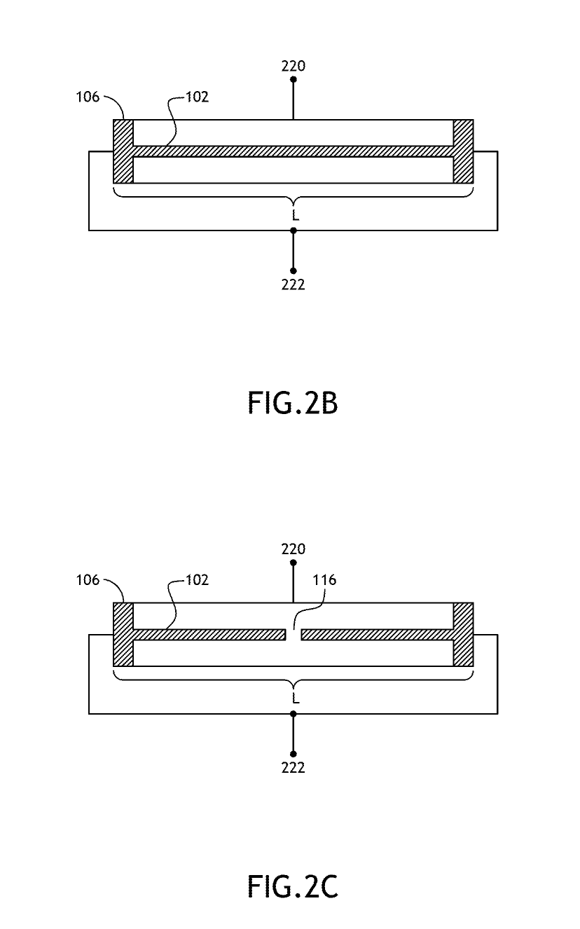

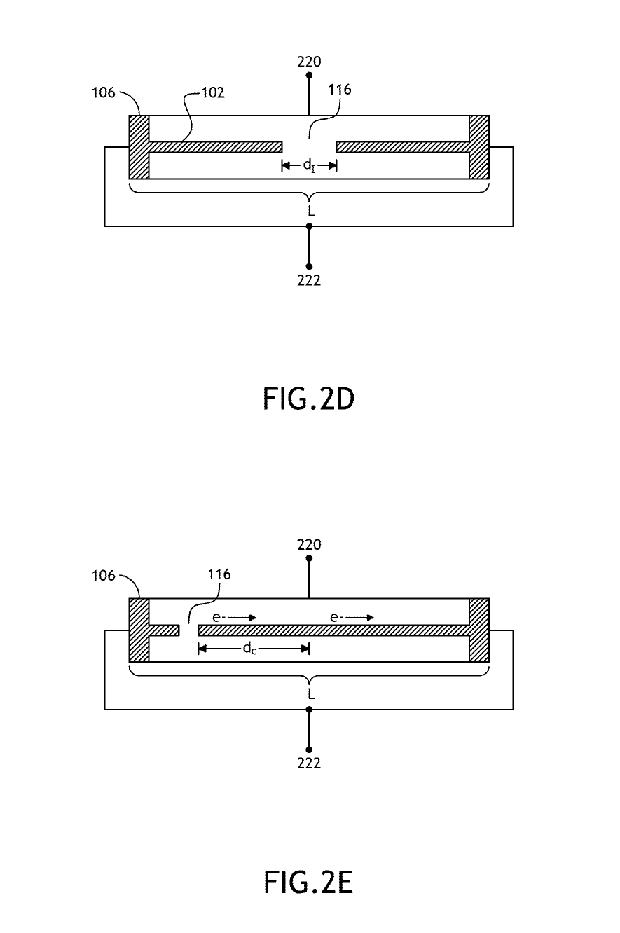

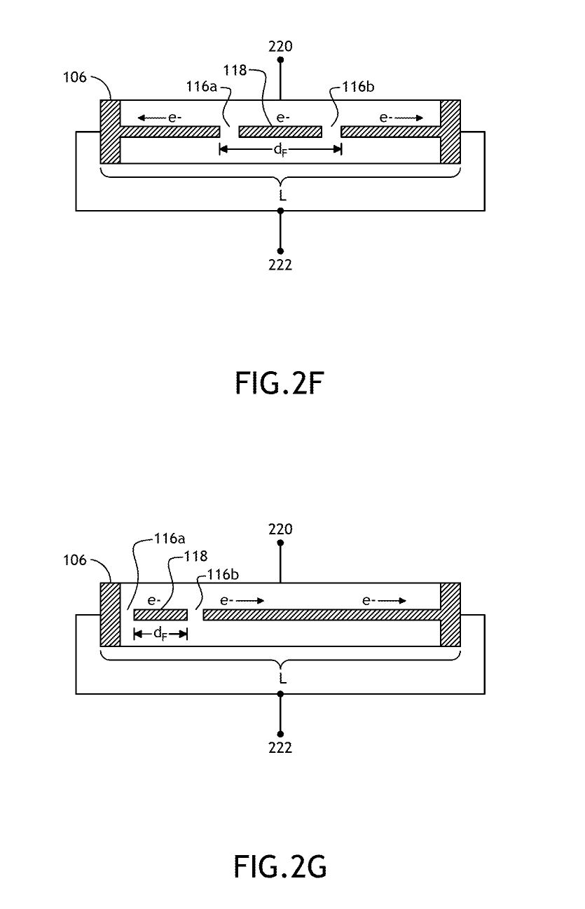

FIG. 2A illustrates a block diagram view of a system 200 for characterizing efficiency impact caused by one or more interruption defects of one or more photovoltaic cells, in accordance with one embodiment of the present invention. In one aspect, the system 200 may include one or more inspection systems 204 suitable for acquiring one or more sets of inspection data (e.g., imagery data) from at least a portion of one or more photovoltaic cells (e.g., solar cells). The system 200 may include a computer control system 201 equipped with one or more processors 202. The computer control system 201 may further include a non-transitory storage medium 206 (i.e., memory medium) containing program instructions 210 configured to cause the one or more processors 202 to carry out one or more of the various steps described throughout the present disclosure. In one aspect of the present invention, the one or more processors 202 of the computer control system 201 are configured to: receive the one or more inspection data sets acquired from a portion of the photovoltaic cell 100 via the one or more inspection systems 204; identify one or more interruption defects 116 in one or more fingers 102 of an electrode (e.g., front side electrode contact 104) of the photovoltaic cell 100 utilizing the one or more inspection data sets; determine one or more spatial parameters associated with the one or more identified interruption defects and/or one or more floating finger 118 portions of the one or more fingers 102 created by two or more identified interruption defects 116; determine an interruption-defect-induced efficiency loss of the photovoltaic cell 100 based the one or more spatial parameters associated with the one or more identified interruption defects 116 and/or the one or more floating finger portions 118 of the one or more fingers 102 created by two or more identified interruption defects 116.

The one or more inspection systems of the present invention may include any inspection system known in the art. For example, the one or more inspection systems 204 may include, but are not limited to, a bright field (BF) inspection system, a dark field (DF) inspection system, and the like. In another example, the one or more inspection systems 204 may include, but are not limited to, an electron beam inspection system. In a general sense, the one or more inspection systems 204 of the present invention may include any device or system suitable for imaging the electrode structure of a portion of a photovoltaic cell 100.

In one aspect of the present invention, the one or more processors 202 of the computer control system 201 may receive inspection data of a portion of a front electrode contact 104 of photovoltaic cell 100 from one or more inspection devices 204 (e.g., inspection device 1, inspection device 2, and up to and including inspection device N). For example, the one or more inspection devices 204 may be associated with one or more semiconductor wafer process tools (not shown) utilized to fabricate the one or more photovoltaic cells 100. For instance, the one or more inspection device 204 may acquire imagery data of the surface of the photovoltaic cell 100 utilizing an optical detector (e.g., CCD camera) at various steps throughout the photovoltaic device fabrication process as it is processed by the respective process tools. In another instance, the one or more inspection device 204 may acquire imagery data of the surface of the photovoltaic cell 100 utilizing an optical detector following fabrication of photovoltaic device.

In a further embodiment, the one or more inspection systems 204 may be communicatively coupled to the control system 201 via a data coupling (e.g., wireline data coupling or wireless data coupling). For example, each of the one or more inspection systems 204 may transmit inspection data to the one or more processors of the control system 201 via a data connection. In another example, the one or more inspection systems 204 may transmit inspection data to an inspection data database 208 of the memory 206 of the control system 201 via a data connection. In this regard, the inspection data may be maintained in the memory 206 and retrieved at a later time by processor 202, allowing the system 200 to perform the various steps of the present invention at any time following inspection of the one or more photovoltaic cells 100.

In another aspect of the present invention, the one or more processors 202 of the system 200 may identify one or more interruption defects 116 in one or more fingers 102 of an electrode contact of a photovoltaic cell 100 utilizing the one or more inspection data sets acquired using the inspection system 204. For example, utilizing the inspection data from the one or more inspection systems 204 and image analysis software known in the art, the system 200 may identify one or more interruption defects 116 present in one or more fingers 102 of a front electrode contact of photovoltaic cell 100. For instance, as shown in FIGS. 1G and 1H, the one or more processors 202 of the control system 201 may identify one or more finger interruption defects, which amount to discontinuities in the electrode finger structure that connects one bus bar 106 of the front electrode contact 106 to an adjacent bus bar.

In another aspect of the present invention, the one or more processors 202 of the system 200 may determine one or more spatial parameters associated with the one or more identified interruption defects 116 and/or one or more floating finger portions 118 of the one or more fingers 102 created by two or more identified interruption defects 116. For example, imagery processing and analysis software may be utilized by the one or more processors 202 to determine one or more spatial parameters associated with one or more interruption defects 116 present along a finger 102 of the photovoltaic cell 100. By way of another example, in the event two or more interrupts exist along a single finger between two adjacent bus bars 106, such as 116a and 116b of instance 138 of FIG. 1H, the one or more processors 202 may determine one or more spatial parameters of a floating finger 118 portion of the cell 100 created due to the neighboring discontinuities 116a and 116b.

In a further aspect, the one or more processors 202 may determine a spatial position of one or more identified interruption defects of one or more fingers and/or one or more floating finger portions of one or more fingers of the photovoltaic cell 100. In one embodiment, the one or more processors 202 may determine a position of one or more interruption defects 116 along a finger 102 of a photovoltaic cell 100. For example, as shown in FIG. 1G, the one or more processors 202 may determine a position of a given interrupt defect 116 relative to a center of a finger spanning two adjacent bus bars 106. In another example, the position of interrupt defect 116 may be expressed relative to one of the bus bars 106 connected to the given finger 102.

In another embodiment, the one or more processors 202 may determine a position of a floating finger section 118 created by two interrupt defects (e.g., 116a and 116b of instance 138 or 140 of FIG. 1H) along a common finger 102 of a photovoltaic cell 100. For example, as shown in FIG. 1H, the one or more processors 202 may determine a position of one or more floating fingers relative to a center of a finger spanning two adjacent bus bars 106. In another example, the position of a floating finger section 118 may be expressed relative to one of the bus bars 106 connected to the given finger 102. In this regard, the one or more processors 202 may utilize the position data associated with the two interruption defects 116a, 116b responsible for creating a given floating finger section 118 to deduce the position of the center of the given floating finger section 118. In addition, it is noted that the positions three or more interruption defects (e.g., 116a-116e of instance 142 of FIG. 1H) may be used to determine the spatial positions of two or more floating finger sections (e.g., 118a-118d of instance 142 of FIG. 1H) of a given finger 102.

In a further embodiment, the one or more processors 202 may determine a spatial position of one or more identified interruption defects utilizing design data (e.g., CAD data) of the one or more photovoltaic cells 100. In this regard, the position of one or more interrupt defect 116 may be determined in design space of the one or more photovoltaic cells 100. In a general sense, design data may include any design data or design data proxy known in the art. The use of design data to determine the positions of inspection data is described generally in U.S. patent application Ser. No. 11/561,735 by Kulkarni et al., filed on Nov. 20, 2006, which is incorporated herein by reference in the entirety.

As will be discussed in greater detail further herein, the position of one or more interruption defects 116 and/or one or more floating finger sections 118 along a given finger 102 may be used by the present invention to determine or estimate the impact of the given interruption defect 116/floating finger section 118 on the efficiency of the photovoltaic cell 100 by providing an estimate of the resistive loss generated by the given interruption defect/floating finger section being located at a non-centered position between two adjacent bus bars 106.

In a further aspect, the one or more processors 202 may determine a size of one or more identified interruption defects of one or more fingers and/or one or more floating finger portions of one or more fingers of the photovoltaic cell 100. In one embodiment, the one or more processors 202 may determine a size (e.g., length) of one or more interruption defects 116 along a finger 102 of a photovoltaic cell 100. For example, as shown in FIG. 1G, the one or more processors 202 may determine a size of a given interrupt defect 116. For instance, the size determination may include an absolute size determination or a relative size determination (e.g., relative to a standardized interruption defect or relative to the length of a finger 102). In this regard, the one or more processors 202 may analyze the identified interruption defects (i.e., identified using inspection data) and discern a size difference between a first interruption defect and an additional interruption defect. For instance, the interruption defect 116 of instance 126 is larger than the interruption defect 116 of instance 124 of FIG. 1G.

In another embodiment, the one or more processors 202 may determine a size of one or more floating finger sections 118 along a finger 102 of a photovoltaic cell 100. For example, as shown in FIG. 1H, the one or more processors 202 may determine a size of a given floating finger section 118 created by two interrupt defects 116a, 116b. For instance, the size determination of a given floating finger section 118 may include an absolute size determination or a relative size determination (e.g., relative to a standardized floating finger section or relative to the length of a finger 102). In this regard, the one or more processors 202 may analyze two or more identified floating finger sections 118 (i.e., identified by identifying two or more interruption defects in inspection data) and discern a size difference between a first floating finger section 118 and an additional floating finger section 118. For instance, the floating finger section 118 of instance 138 is smaller than the floating finger section 140 of instance 140, as shown in FIG. 1H.

In a further embodiment, it is recognized that the one or more processors 202 may determine a size of two or more floating finger sections along a finger 102 of a photovoltaic cell 100. It is recognized herein that the collection loss caused by multiple adjacent floating finger sections (e.g., 118a-118d) is similar to an equivalent floating finger section of the same length as the spatial footprint of the multiple floating finger sections of a given finger 102. This is illustrated in instance 140 and instance 142 of FIG. 1H. The collection loss created by disconnecting a portion of the finger from the bus bars 106 is the same in the instance 140 and instance 142. Therefore, in settings where multiple floating finger sections 118 are present on a common finger 102, the one or more processors 202 may determine a size (e.g., length) of the entire group of floating finger sections 118.

As will be discussed in greater detail further herein, the size of one or more interruption defects 116 and/or one or more floating finger sections 118 along a given finger 102 may be used by the present invention to determine or estimate the impact of the given interruption defect 116/floating finger section 118 on the efficiency of the photovoltaic cell 100 by providing an estimate of the collection losses generated by the given interruption defect/floating finger section being located along a finger 102 between two adjacent bus bars 106.

In a further aspect, the one or more processors 202 may determine a quantity of identified interruption defects of one or more fingers and/or one or more floating finger portions of the one or more fingers of the photovoltaic cell 100. In one embodiment, the one or more processors 202 may determine the number of one or more interruption defects 116 along a given finger 102 of a photovoltaic cell 100. For example, as shown in FIG. 1H, the one or more processors 202 may determine the number of interrupt defects 116 along a selected finger 102 between two adjacent bus bars 106. In another embodiment, the one or more processors 202 may determine the number of floating finger sections along a given finger 102 of a photovoltaic cell 100. For example, as shown in FIG. 1H, the one or more processors 202 may determine the number floating finger sections 118 along a selected finger 102 between two adjacent bus bars 106. It is recognized herein that the number of identified interruption defects 116 present in a given finger 102 may be used to determine the number of floating finger sections 118 present in the given finger 102 (e.g., there exist N−1 floating finger sections when N interruption defects are present in a finger).

As will be discussed in greater detail further herein, the number of one or more interruption defects 116 and/or floating finger sections 118 along one or more fingers 102 of a photovoltaic cell 100 may be used by the present invention to determine or estimate the impact of the given interruption defects/floating finger sections on the efficiency of the photovoltaic cell 100 by providing an estimate of the aggregated losses (e.g., resistive losses or collection losses) generated by the given interruption defects/floating finger sections being located along one or more fingers 102 of a photovoltaic cell 100.

In a further embodiment, the one or more processors 202 may apply a binning procedure in order to determine the number of interruption defects and/or the number of floating finger sections falling within a particular size range or a spatial section. In this regard, it is noted that the binned data may then be used to determine the aggregated impact of all or some of the interrupt defects 116 and/or floating finger sections 118 on the efficiency of the photovoltaic cell 100.

In another aspect of the present invention, the one or more processors of the system 200 may determine an interruption-defect-induced efficiency loss of the at least one photovoltaic cell 100 based on the determined one or more spatial parameters associated with the one or more identified interruption defects 116 and/or the one or more floating finger portions 118 of the one or more fingers 102 created by two or more identified interruption defects 116. In this regard, the one or more processors 202 of the control system 201 may generate an estimate for the efficiency impact created by the presence of one or more interruption defects along one or more fingers 102 of a photovoltaic cell 100. The existence of two or more interruption defects along a single finger 102 of a photovoltaic cell 100 leads to the creation of a floating finger 118, which is nearly completely isolated from either bus bar 106a or 106b. As such, the one or more processors 202 of the computer control system 201 may act to estimate the interruption-defect-induced efficiency loss of a photovoltaic cell 100 using the determined spatial parameters associated with the identified interruption defects (e.g., 116a and 116b of case 138) and the determined spatial parameters associated with one or more floating fingers (e.g., 118 of case 138 or 118a-118d of case 142) of a finger 102 created by two or interrupt defects being present on the same finger 102.

In another aspect of the present invention, the one or more processors 202 of the system 200 may determine an interruption-defect-induced efficiency loss of the at least one photovoltaic cell based on the determined one or more spatial parameters associated with the at least one of the one or more identified interruption defects 116 and/or the one or more floating finger portions 118 of the one or more fingers 102 created by two or more identified interruption defects. In this regard, the one or more processors 202 may execute an efficiency loss estimation algorithm 212 included in a set of program instructions 210 carried on a memory medium 206 of the computer control system 201 in order to generate an efficiency loss estimate caused by the one or more interruption defects 116 and/or one or more floating finger sections 118 of a photovoltaic cell 100. For example, the efficiency loss estimation algorithm 212 may accept as an input one or more spatial parameters (e.g., number, size, position, and the like) associated with the one or more identified interruption defects 116 and/or the one or more floating finger sections 118 of a photovoltaic cell 100. The efficiency loss estimation algorithm 212 may then output an estimated efficiency loss value 212 based on the inputted spatial parameter values associated with the one or more identified interruption defects 116 and/or the one or more floating finger sections 118 of a photovoltaic cell 100.

It is recognized herein that the efficiency loss estimation algorithm 212 of the present invention may include known or “learned” relationships between any of the spatial parameters described previously herein to determine a efficiency loss for a given photovoltaic cell 100, which is a combination of the resistive losses (i.e., losses due to a defect 116/floating finger section 118 being located off-center in a given finger 102) and collection losses (i.e., losses due to charge carriers having no conductive path to a bus bar 106) generated by the various interruption defects 116 and floating finger sections 118 of the photovoltaic cell 100. In this sense, the algorithm 212 may utilize one or more of the determined spatial parameters associated for each identified interruption defect 116/floating finger section 118 to determine an estimate for the resistive losses and collection losses present in a given finger 102 in order to generate the net efficiency losses in the finger 102 of a photovoltaic cell 100. Then, the algorithm 212 may aggregate the net efficiency losses in each finger 102 having identified interruption defects 116/floating finger sections 118 in order to determine the cell-wide efficiency loss.

It is further recognized that the algorithm 212 may utilize information associated with the layout or design of the photovoltaic cell 100 in order to generate an estimate for efficiency loss. For example, the determination of the impact on efficiency loss may include the incorporation of a layout of a photovoltaic cell's metallic line pattern. In this sense, the algorithm 212 may incorporate at least one of the following factors when generating the efficiency loss: i) number of line fingers or spacings; ii) width of fingers; iii) number of bus bars; and iv) width of bus bars.

FIGS. 2B through 2G illustrate a series of example interruption defect configurations present in a single finger of a photovoltaic cell, in accordance with one embodiment of the present invention. It is noted herein that each of the following examples is not limiting and are merely presented for purposes of illustration. It is further contemplated that the algorithm 212 may incorporate a “rule” or “association” for each of the idealized configurations depicted in FIGS. 2B through 2G. The rules corresponding to each of the settings in FIGS. 2B-2G may be combined with one another to provide a more thorough estimate of efficiency loss in a given finger of a photovoltaic cell 100. In addition, while FIGS. 2B-2G depict a single finger 102 it is noted that these concepts may be extended to each finger of a photovoltaic cell 100, thereby allowing the algorithm 212 to aggregate the various efficiency loss effects to determine a cell-wide efficiency loss.

Referring now to FIG. 2B, a single finger 102 having no interrupt defects 116 is illustrated, in accordance with the present invention. The finger 102 is idealized to have a length of “L” and is coupled to the front-side electrode 222, with the backside electrode 220 disposed on the opposite side of the semiconductor junction (not shown in FIG. 2B). The finger 102 of FIG. 2B represents the baseline efficiency configuration. The algorithm 212 may be programmed to output an efficiency loss of 0% for a finger 102 in the event the control system 202 identifies zero interruption defects along the given finger 102, as shown in FIG. 2B.

Referring now to FIGS. 2C and 2D, a single finger 102 having a single interrupt defect positioned at the center of the finger 102 is illustrated, in accordance with the present invention. It is noted that due to the interruption defect 116 a portion of the electrons generated by light incident on the underlying semiconductor junction (not shown) cannot be collected since those electrons do not have access to a conduction path. As such, the efficiency loss is non-zero. Given an interrupt defect 116 having a characteristic length of dₗ, as shown in FIG. 2D, the efficiency loss estimation algorithm 212 may provide an estimate for the efficiency loss caused by the loss of electron collection ability of the finger 102. For example, the algorithm 212 may be programmed with a predefined relationship between the relative size of the interrupt defect (e.g., with respect to the size of the finger) and the estimated efficiency loss due to the interruption defect 116. For instance, the estimated efficiency loss caused by the interrupt defect 116 may be a direct function of the size of the interrupt defect 116 relative to the size of the finger 102. In this sense, the percentage of efficiency loss may be provided by:

$$Loss \% = \frac{{d}_{I}}{L} \qquad Eq . 1$$

For example, an interruption defect 116 having a length of 10 mm length positioned at the center of the finger 102 (i.e., so resistive losses are negligible) having a length of 100 mm has a corresponding efficiency loss (due to collection loss) of 10%. By way of another example, an interruption defect 116 having a length of 30 mm and a finger having a length of 100 mm gives rise to an efficiency loss of 30%. In a further embodiment, the algorithm 212 may include further features which act to correct the simplified model provided above. For instance, it is recognized herein that electrons in an interruption defect region may alternatively travel laterally, in which case they may encounter a non-defective portion of an adjacent finger (not shown), leading to the collection of these electrons. As such, the efficiency loss due to an interruption defect 116 positioned at the center of a finger 100 will fall below the prediction provided in equation 1. It is noted that any model known in the art suitable for modeling the efficiency loss caused by an interruption defect may be incorporated into the algorithm 212. It is further noted that the estimation of the collection-based efficiency losses provided by the present invention may incorporate numerous consideration. For instance, it should be recognized that the collection-based loss of efficiency may impact short circuit current (ISC) in the photovoltaic cell 100.

Referring now to FIG. 2E, a single finger 102 having a single interrupt defect positioned at a non-center position of the finger 102 is illustrated, in accordance with the present invention. It is noted herein that in the event an interrupt defect 116 is located at a non-center position, all or some of the current collected by the finger 102 must flow to contact point (i.e., bus bar 106) that is a larger distance from the collection point had no defect been present. In this sense, the electrons collected by the region 222, as shown in FIG. 2E, must now travel a distance farther than they would have traveled had the defect 116 not been present. Given an interrupt defect 116 at a distance d_{c} from the center of the finger then the percentage of collected electrons having to travel a larger distance may be estimated by:

$$\% of electrons ∝ \frac{2 {d}_{c}}{L} \qquad Eq . 2$$

Given that the resistive loss for a given finger is “R %” when an interrupt defect is at the far end of a given finger (i.e., located at the bus bar connection point) then the resistive loss for a single finger 102 having an interruption defect at a non-center position may range from 0% to R %, where the loss is R % when the interrupt is at an extreme location of the line finger 102.

$$Loss \% ∝ R \frac{2 {d}_{c}}{L} \qquad Eq . 3$$

For example, in the event that R is equal to 5%, an interruption defect 116 situated at the center of the line finger 102 will result in an efficiency loss % of zero, while a defect 116 positioned at the extreme end of a line finger will result in an efficiency loss % of 5%. For interruption defects 116 position between the center and one of the far ends of the line finger 102, the efficiency loss percentage falls between 0 and 5%.

In a further embodiment, the algorithm 212 may include further features which act to correct the simplified model provided above. For instance, as discussed previously herein, it is recognized herein that electrons in an interruption defect region may alternatively travel laterally, in which case they may encounter a non-defective portion of an adjacent finger (not shown), creating an alternate conduction path for these electrons. As such, the efficiency loss due to an interruption defect 116 positioned at the far end of a finger 102 will fall below the prediction provided in equation 3. Applicant notes that equation 3 is provided merely for purposes of illustration. It is noted herein that the relationship between Loss % and the distance from center need not be linear in nature. Any model known in the art suitable for modeling the resistive efficiency loss caused by an interruption defect may be incorporated into the algorithm 212. For example, theoretical models which act to describe the theoretical relationship between resistive losses and finger line position may be incorporated into the algorithm 212. By way of another example, the algorithm 212 may utilize an empirically generated resistive loss database. The resistive loss database may be empirically generated by measuring resistive loss at multiple locations along one or more test fingers of one or more test photovoltaic cells under conditions similar to the fabrication and/or operating conditions of the product photovoltaic cells 100. It is further noted that the estimation of the resistive-based losses provided by the present invention may incorporate numerous considerations. For instance, it should be recognized that the resistive-based loss in efficiency may impact series resistance and fill factor in the photovoltaic cell 100.

Referring now to FIG. 2F, a single finger 102 having a single floating finger section 118 positioned at a center position of the finger 102 is illustrated, in accordance with the present invention. In the same manner an interrupt defect 116 of size dₗ may have an efficiency loss estimation given by equation 1 above, the estimated efficiency loss associated with a floating finger section 118 of size d_{F} (located at the center of the line finger 102) may be provided by:

$$Loss \% = \frac{{d}_{F}}{L} \qquad Eq . 4$$

where d_{F} represents the length of the one or more floating finger sections 118. It is noted herein that the floating finger section 118, is by definition, a region of the finger 102 electrically isolated from the remainder of the finger 102. As such, the electrons collected locally by the floating finger section 118 have no means to conduct to the bus bars 106 of the photovoltaic cell 100. Therefore, the presence of a floating finger section 118 has a similar efficiency loss impact as an interruption defect 116 at the same location and of the same size. It is further recognized that the algorithm 212 may treat the size of a given floating finger section 118 as the distance extending from the outermost portions of the interrupt defects 116a, 116b defining the given floating finger section 118, as shown in FIG. 2F. It is further contemplated that the algorithm 212 may treat a series of neighboring floating finger sections 118 as a single aggregated section (e.g., see floating finger sections in FIG. 1H). For the purposes of efficiency loss impact determination by the algorithm, the key characteristic is the amount of the finger line 102 that is removed from the finger line 102 or electrically isolated from the bus bars 106. The distance associated with that measure may then be used to estimate the efficiency loss of the photovoltaic cell as a result of collection efficiency loss.

Referring now to FIG. 2G, a single finger 102 having a single floating finger section 118 positioned at a non-center position of the finger 102 is illustrated, in accordance with the present invention. It is noted herein that in the same manner a non-centered position of the interruption defect of FIG. 2E gave rise to a non-zero resistive efficiency loss, a floating finger section 118 located at a non-centered position will generate a resistive-based impact on efficiency. In this regard, the efficiency loss associated with the resistive efficiency loss due to the non-centered position of the floating finger section 118 may be estimated using equation 3, wherein the distance, d_{c}, is the distance from the center of the line finger 102 to the floating finger section 118.

In addition, due to the spatial footprint of the floating finger section 118, the floating finger section 118 will also contribute to a net efficiency loss via collection losses since the electrons collected by the floating finger section 118 are isolated from the remainder of the line finger 102. As such, the net efficiency losses resulting from a floating finger section 118 (or an interruption defect) actually represent a convolution of resistive-based efficiency losses and collection-based efficiency losses.

In determining the net impact the floating finger section 118 has on efficiency of the photovoltaic cell 100, the system 200 may first determine the collection losses associated with the floating finger section 118 (or the interruption defect 116). Then, the system 200 may correct the maximum achievable efficiency with respect to the estimated collection losses. Then utilizing the corrected maximum efficiency the algorithm 212 of the system 200 may apply a similar methodology, as described previously herein, to determine the impact of resistive losses, due to a non-centered position of the section 118, on the net efficiency of the photovoltaic cell.

For example, in the event that the floating finger section represents 10% of the total length L of the finger 102, the estimated collection-based losses amount approximately to 10% of the total efficiency of the device. As such, the total achievable efficiency after correcting for collection losses is 90%. In turn, if the resistive-based efficiency impact is 5% (due to the position of the floating finger section 118) then the overall resistive-based efficiency loss due to the floating finger section 118 of FIG. 2G is given by 4.5% (90% by 5%). Summing the resistive loss and the collection-based loss then provides a net efficiency lost of 14.5% (10%+4.5%).

It is further recognized that the above methodology may be equally applicable to interruption defects 116 having a given size. Moreover, the above methodology may also be extended to multiple floating finger sections 118 and/or multiple interruption defects 116 present in a single finger 102. In addition, it is further contemplated that the effects described above with respect to a single line finger may be aggregated across all or at least some of the fingers 102 to determine the impact of multiple interruption defects and/or multiple floating finger sections 118 on the efficiency of a given photovoltaic cell 100.

Referring again to FIG. 2A, the one or more processors 202 of the control system 201 may execute an interruption criticality index (ICI) algorithm 214 suitable for characterizing interruption defect impact on efficiency, in accordance with an alternative embodiment of the present invention.

In one aspect, the system 200 may determine a position of one or more interruption defects 116 in a photovoltaic cell 100 utilizing inspection data obtained from one or more inspection systems 204. In this regard, the system 200 may determine a position of one or more interruption defects in the same manner as described previously herein. Then, one or more processors 202 of the system 200 may then apply the ICI algorithm 214 in order to estimate the impact of the one or more interruption defects on efficiency of the photovoltaic cell 100.

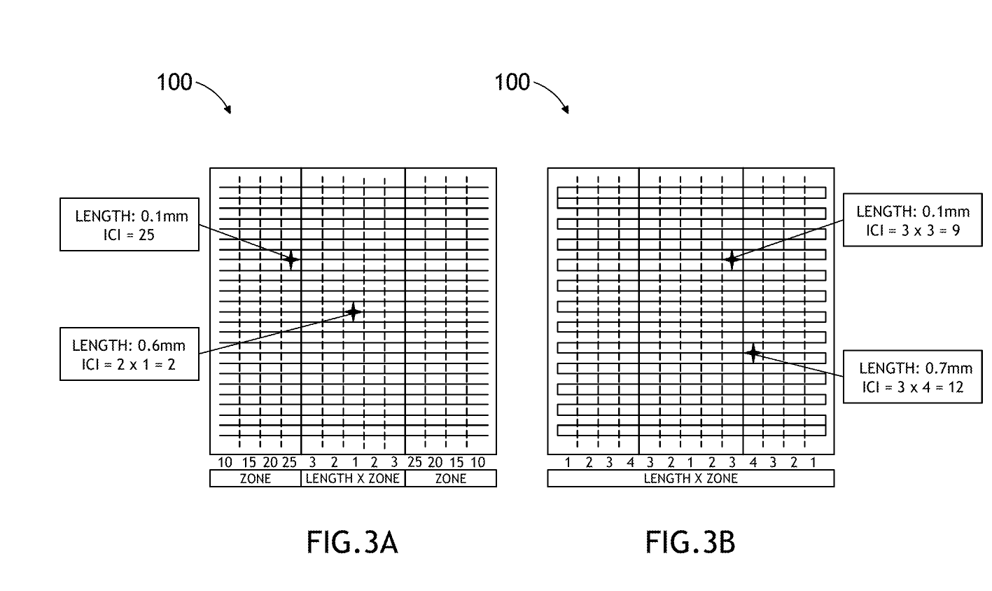

Referring now to FIGS. 3A and 3B, the ICI algorithm 214 may include a set of rules that relate a group of indexes to different regions of the photovoltaic cell 100. In addition, the ICI algorithm 214 may incorporate the size of a given interruption defect 116 into the calculation carried out to estimate efficiency impact of the one or more defects of the photovoltaic cell 100.

In this sense, the algorithm 214 may assign a “length index” and/or a “zone index” to each identified interruption defect found on the photovoltaic cell 100. In this regard, the system 200 may establish a length and zone indexing scheme, which allows the algorithm 214 to carry out a “look up” routine, which receives the position and size of an interruption defect as an input. The algorithm 214 may then output an efficiency impact “score.” This score may then be utilized by a user to make a determination concerning the quality of the photovoltaic cell 100.

In one embodiment, the ICI of each interruption defect may include determining a length index of each interruption defect identified on the photovoltaic cell 100. For example, a predetermined length/length index relationship may be established and stored in the memory 206. For instance, a database similar to the contents of the following table may be stored in the memory 206 and used by the one or more processors 202 to assign a length index value to each identified interruption defect.

| Length (mm) | Index |
|---|---|
| 0.1-0.3 | 1 |
| 0.4-0.6 | 2 |
| 0.7-1.0 | 3 |

It is recognized that the above table is merely provided for illustrative purposes and should not be interpreted as limiting. It is noted that any number of indexes, index values, and length ranges may be utilized in the context of the present invention.

In another embodiment, as shown in FIGS. 3A and 3B, the location of the identified interruption defect may be assigned a “zone index.” For example, as shown in FIG. 3A, each region of the photovoltaic cell 100 may be assigned a zone index value. An interruption defect indentified in a zone is then assigned the zone index corresponding with that region. The various zone indexes may be assigned based on the magnitude of potential efficiency impact of an interruption defect located in the given zone. In this sense, more critical regions may be assigned higher number index values, while less critical regions may be assigned lower index values (note in alternative indexing schemes small numbers, fractional numbers, negative numbers and the like may be indicative of large efficiency loss).

In a further embodiment, a combined index may be determined by one or more processors 202 by multiplying a zone index and a length index associated with a given identified interruption defect. For example, as shown in FIG. 3A, an interrupt defect having a zone index of 1 and a length index of 2 (e.g., length 0.4-0.6 mm) has a total index of 2 (1×2). In a further embodiment, the applicability of the combined index may be a function of the position of the interrupt defect on the photovoltaic cell 100. For instance, as shown in FIG. 3A, combined indexes are generated only for interrupt defects found in the center zones (labeled as “length×zone”), while only a zone index is applied for interrupt defects found outside this region.

In an additional aspect, it is recognized that different photovoltaic cell finger designs may impact both the specific index values applied in determining a zone index or length index database as well as whether or not to apply the combined index methodology discussed above. For example, as shown in FIGS. 3A and 3B, a user may choose to apply the combined zone step in an open finger photovoltaic cell setting, while applying only a zone index analysis when in a closed finger photovoltaic cell setting.

In another embodiment, the one or more processors 202 of the system 200 may determine an aggregated index value for an entire photovoltaic cell using the ICI algorithm 214. In this sense, the algorithm 214 may direct the one or more processors to sum the index values of all of the indentified interrupt defects of the photovoltaic cell. For example, as shown in FIG. 3A, in a cell 100 having two interrupt defects with individual indexes of 25 and 2, respectively, the aggregated index may be calculated to be 27. In another example, as shown in FIG. 3B, in a cell 100 having two interrupt defects with individual indexes of 9 and 12, respectively, the aggregated index may be calculated to be 21. In this sense, a user or the control system 201 may utilize the aggregated indexes obtained from two or more photovoltaic cells for purposes of classification, allowing a user to estimate the relative efficiency impact caused by defects present in different photovoltaic cells.

In a further embodiment, the system 200 may include a display device 216 communicatively coupled to the one or more processors 202 and configured to display one or more results generated by the one or more processors 202. The display device 216 may include any display device known in the art. For example, the display device 216 may include, but is not limited to, a liquid crystal display (LCD), an organic light-emitting diode (OLED) based display device or a cathode ray tube (CRT) display device. Those skilled in the art should recognize that a variety of display devices may be suitable for implementation in the present invention and the particular choice of display device may depend on a variety of factors, including, but not limited to, form factor, cost, and the like.

In another aspect, the one or more processors 202 are in communication with a memory medium 206. The memory medium 206 may be configured to store one or more sets of photovoltaic cell inspection data in an inspection database 208. In this regard, the one or more processors 202 of the computer control system 201 may store all or a portion of the inspection data received by the one or more processors 202 (e.g., received from the one or more inspection devices 204, received from an additional system or tool communicatively coupled to control system 201, received from a portable memory medium, such as a solid state memory device, an optical memory device, a magnetic memory device, and the like) in the inspection data database 208 maintained in memory 206. In addition, the one or more memory media 206 may store the program instructions suitable for execution by the communicatively coupled one or more processors 202. Program instructions 210 implementing methods such as those described herein may be transmitted over or stored on a carrier medium. The carrier medium may be a transmission medium such as a wire, cable, or wireless transmission link. The carrier medium may also include a memory medium 116 such as a read-only memory, a random access memory, a magnetic or optical disk, or a magnetic tape.

In general, the term “processor” may be broadly defined to encompass any device having one or more processors, which execute instructions from a memory medium. In this sense, the one or more processors 202 may include any microprocessor-type device configured to execute software algorithms and/or instructions. In one embodiment, the one or more processors 202 may consist of a desktop computer or other computer system (e.g., networked computer) configured to execute a program configured to operate the system 200, as described throughout the present disclosure. It should be recognized that the steps described throughout the present disclosure may be carried out by a single computer system or, alternatively, multiple computer systems. Moreover, different subsystems of the system 200, such as the display device 216 or the inspection system 204, may include a processor or logic elements suitable for carrying out at least a portion of the steps described above. Therefore, the above description should not be interpreted as a limitation on the present invention but merely an illustration.

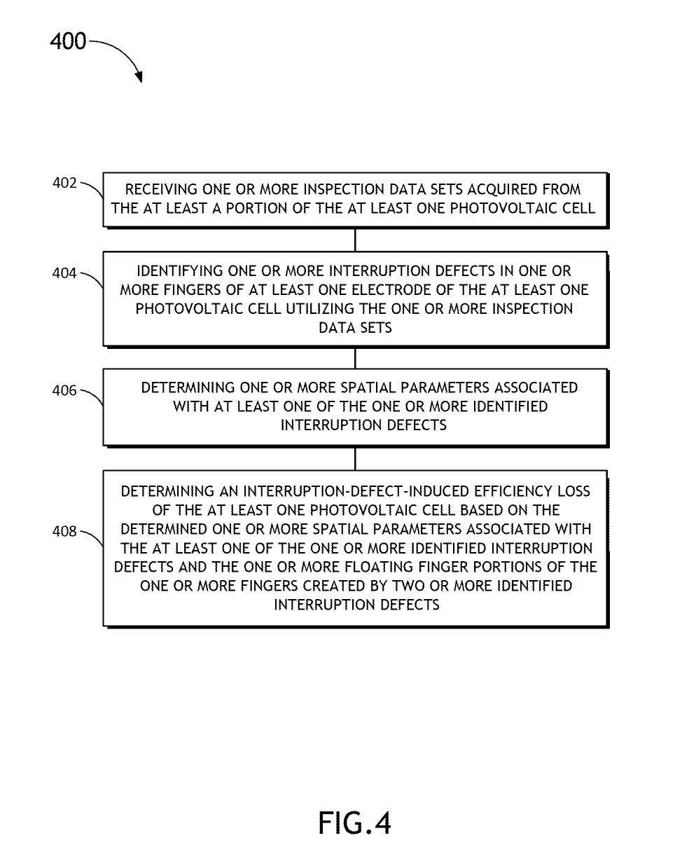

FIG. 4 illustrates a process flow diagram depicting a method 400 for characterizing efficiency impact caused by one or more interruption defects of one or more photovoltaic cells, in accordance with one embodiment of the present invention.

In step 402, the one or more processors 202 of the computer control system 201 may receive one or more inspection data sets, from one or more inspection systems 204, acquired from the at least a portion of the at least one photovoltaic cell 100. In step 404, the one or more processors 202 may identify one or more interruption defects 116 in one or more fingers 102 of at least one electrode of the at least one photovoltaic cell 100 utilizing the one or more inspection data sets. In step 406, the one or more processors 202 may determine one or more spatial parameters (e.g., position, size, quantity, and the like) associated with at least one of the one or more identified interruption defects 116. In step 408, the one or more processors 202 may determine an interruption-defect-induced efficiency loss of the at least one photovoltaic cell 100 based on the determined one or more spatial parameters associated with the at least one of the one or more identified interruption defects 116 and the one or more floating finger portions 118 of the one or more fingers 102 created by two or more identified interruption defects.

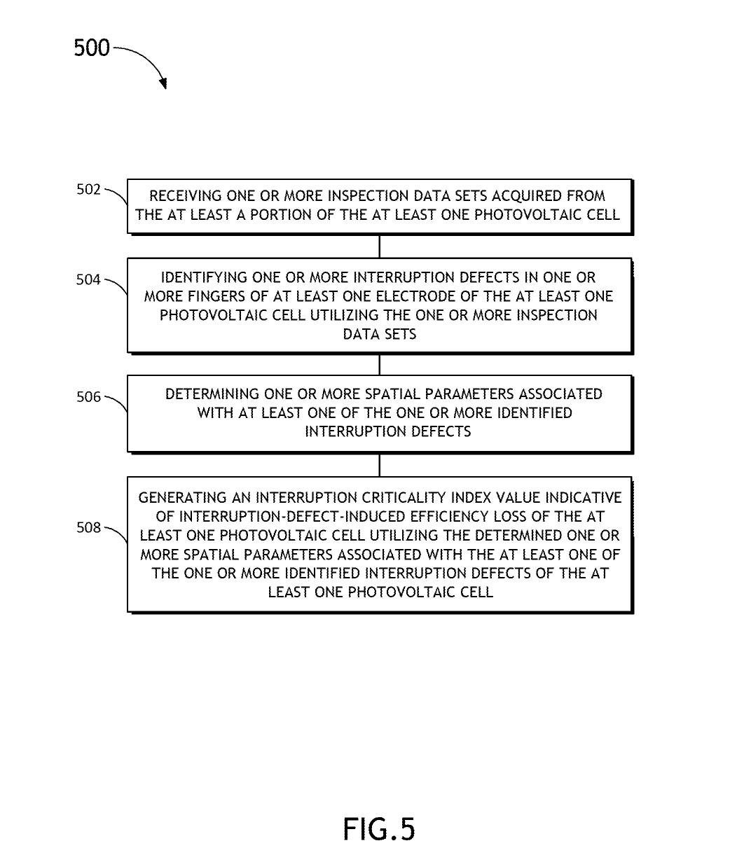

FIG. 5 illustrates a process flow diagram depicting a method 500 for characterizing efficiency impact caused by one or more interruption defects of one or more photovoltaic cells, in accordance with one embodiment of the present invention.

In step 502, the one or more processors 202 of the computer control system 201 may receive one or more inspection data sets, from one or more inspection systems 204, acquired from the at least a portion of the at least one photovoltaic cell 100. In step 504, the one or more processors 202 may identify one or more interruption defects 116 in one or more fingers 102 of at least one electrode of the at least one photovoltaic cell 100 utilizing the one or more inspection data sets. In step 506, the one or more processors 202 may determine determining one or more spatial parameters associated with at least one of the one or more identified interruption defects 116. In step 508, the one or more processors 202 may generate an interruption criticality index (ICI) value indicative of interruption-defect-induced efficiency loss of the at least one photovoltaic cell utilizing the determined one or more spatial parameters associated with the at least one of the one or more identified interruption defects of the at least one photovoltaic cell.

Those having skill in the art will recognize that the state of the art has progressed to the point where there is little distinction left between hardware and software implementations of aspects of systems; the use of hardware or software is generally (but not always, in that in certain contexts the choice between hardware and software can become significant) a design choice representing cost vs. efficiency tradeoffs. Those having skill in the art will appreciate that there are various vehicles by which processes and/or systems and/or other technologies described herein can be effected (e.g., hardware, software, and/or firmware), and that the preferred vehicle will vary with the context in which the processes and/or systems and/or other technologies are deployed. For example, if an implementer determines that speed and accuracy are paramount, the implementer may opt for a mainly hardware and/or firmware vehicle; alternatively, if flexibility is paramount, the implementer may opt for a mainly software implementation; or, yet again alternatively, the implementer may opt for some combination of hardware, software, and/or firmware. Hence, there are several possible vehicles by which the processes and/or devices and/or other technologies described herein may be effected, none of which is inherently superior to the other in that any vehicle to be utilized is a choice dependent upon the context in which the vehicle will be deployed and the specific concerns (e.g., speed, flexibility, or predictability) of the implementer, any of which may vary. Those skilled in the art will recognize that optical aspects of implementations will typically employ optically-oriented hardware, software, and or firmware.

Those skilled in the art will recognize that it is common within the art to describe devices and/or processes in the fashion set forth herein, and thereafter use engineering practices to integrate such described devices and/or processes into data processing systems. That is, at least a portion of the devices and/or processes described herein can be integrated into a data processing system via a reasonable amount of experimentation. Those having skill in the art will recognize that a typical data processing system generally includes one or more of a system unit housing, a video display device, a memory such as volatile and non-volatile memory, processors such as microprocessors and digital signal processors, computational entities such as operating systems, drivers, graphical user interfaces, and applications programs, one or more interaction devices, such as a touch pad or screen, and/or control systems including feedback loops and control motors (e.g., feedback for sensing position and/or velocity; control motors for moving and/or adjusting components and/or quantities). A typical data processing system may be implemented utilizing any suitable commercially available components, such as those typically found in data computing/communication and/or network computing/communication systems.

The herein described subject matter sometimes illustrates different components contained within, or connected with, different other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected”, or “operably coupled”, to each other to achieve the desired functionality, and any two components capable of being so associated can also be viewed as being “operably couplable”, to each other to achieve the desired functionality. Specific examples of operably couplable include but are not limited to physically mateable and/or physically interacting components and/or wirelessly interactable and/or wirelessly interacting components and/or logically interacting and/or logically interactable components.

While particular aspects of the present subject matter described herein have been shown and described, it will be apparent to those skilled in the art that, based upon the teachings herein, changes and modifications may be made without departing from the subject matter described herein and its broader aspects and, therefore, the appended claims are to encompass within their scope all such changes and modifications as are within the true spirit and scope of the subject matter described herein.

Furthermore, it is to be understood that the invention is defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

Although particular embodiments of this invention have been illustrated, it is apparent that various modifications and embodiments of the invention may be made by those skilled in the art without departing from the scope and spirit of the foregoing disclosure. Accordingly, the scope of the invention should be limited only by the claims appended hereto.

It is believed that the present disclosure and many of its attendant advantages will be understood by the foregoing description, and it will be apparent that various changes may be made in the form, construction and arrangement of the components without departing from the disclosed subject matter or without sacrificing all of its material advantages. The form described is merely explanatory, and it is the intention of the following claims to encompass and include such changes.

What is claimed:

1. A system for characterizing efficiency impact caused by one or more interruption defects of one or more photovoltaic cells, comprising:
one or more inspection systems configured to acquire one or more sets of inspection data from at least a portion of at least one photovoltaic cell;
a computer control system communicatively coupled to the one or more inspection systems and configured to:
receive the one or more inspection data sets acquired from the at least a portion of the at least one photovoltaic cell;
identify one or more interruption defects in one or more fingers of at least one electrode of the at least one photovoltaic cell utilizing the one or more inspection data sets;
determine one or more spatial parameters associated with at least one of the one or more identified interruption defects and one or more floating finger portions of the one or more fingers created by two or more identified interruption defects;
determine an interruption-defect-induced efficiency loss of the at least one photovoltaic cell based on the determined one or more spatial parameters associated with the at least one of the one or more identified interruption defects and the one or more floating finger portions of the one or more fingers created by two or more identified interruption defects.

2. The system of claim 1, wherein the computer control system is further configured to determine a quantity of the identified interruption defects in the one or more fingers of the at least one electrode of the at least one photovoltaic cell.

3. The system of claim 1, wherein the computer control system is further configured to determine a spatial position of the identified interruption defects in the one or more fingers of the at least one electrode of the at least one photovoltaic cell.

4. The system of claim 3, wherein the computer control system is further configured to determine a spatial position of the identified interruption defects in the one or more fingers of the at least one electrode of the at least one photovoltaic cell in order to determine an efficiency loss associated with resistive-based efficiency loss in the at least one photovoltaic cell.

5. The system of claim 1, wherein the computer control system is further configured to determine a spatial size of the identified interruption defects in the one or more fingers of the at least one electrode of the at least one photovoltaic cell.

6. The system of claim 5, wherein the computer control system is further configured to determine a spatial size of the identified interruption defects in the one or more fingers of the at least one electrode of the at least one photovoltaic cell in order to determine an efficiency loss associated with collection-based loss in the at least one photovoltaic cell.

7. The system of claim 1, wherein the computer control system is further configured to determine a quantity of the one or more floating finger portions of the one or more fingers created by two or more identified interruption defects of the at least one electrode of the at least one photovoltaic cell.

8. The system of claim 1, wherein the computer control system is further configured to determine a spatial position of the one or more floating finger portions of the one or more fingers created by two or more identified interruption defects of the at least one electrode of the at least one photovoltaic cell.

9. The system of claim 3, wherein the computer control system is further configured to determine a spatial position the one or more floating finger portions of the one or more fingers created by two or more identified interruption defects of the at least one electrode of the at least one photovoltaic cell in order to determine an efficiency loss associated with resistive-based loss in the at least one photovoltaic cell.

10. The system of claim 1, wherein the computer control system is further configured to determine a spatial size of the one or more floating finger portions of the one or more fingers created by two or more identified interruption defects of the at least one electrode of the at least one photovoltaic cell.

11. The system of claim 10, wherein the computer control system is further configured to determine a spatial size of the one or more floating finger portions of the one or more fingers created by two or more identified interruption defects of the at least one electrode of the at least one photovoltaic cell in order to determine an efficiency loss associated with collection-based loss in the at least one photovoltaic cell.

12. The system of claim 1, wherein the computer control system is further configured to determine one or more spatial parameters associated with at least one of the one or more identified interruption defects and one or more floating finger portions of the one or more fingers created by two or more identified interruption defects utilizing one or more sets of design data of the at least one photovoltaic cell.

13. The system of claim 1, wherein the computer control system is further configured to determine an interruption-defect-induced efficiency loss of the at least one photovoltaic cell based on at least one of a determined quantity of the one or more identified interruption defects, a determined spatial position of the one or more indentified interruption defects, and a determined size of the one or more indentified interruption defects.

14. The system of claim 1, wherein the computer control system is further configured to determine an interruption-defect-induced efficiency loss of the at least one photovoltaic cell based on at least one of a determined quantity of the one or more floating finger portions of the one or more fingers created by two or more identified interruption defects, a determined spatial position of the one or more floating finger portions of the one or more fingers created by two or more identified interruption defects, and a determined spatial size of the one or more floating finger portions of the one or more fingers created by two or more identified interruption defects.

15. The system of claim 1, wherein the computer control system is further configured to determine an interruption-defect-induced efficiency loss of the at least one photovoltaic cell based on the determined one or more spatial parameters associated with the at least one of the one or more identified interruption defects and the one or more floating finger portions of the one or more fingers created by two or more identified interruption defects

16. The system of claim 1, wherein the computer control system is further configured to determine an interruption-defect-induced efficiency loss of the at least one photovoltaic cell by aggregating the determined efficiency losses for each finger of the at least one photovoltaic cell.

17. The system of claim 1, wherein the inspection system comprises at least one of a bright field (BF) inspection system and a dark field (DF) inspection system.

18. A system for characterizing efficiency impact caused by one or more interruption defects of one or more photovoltaic cells, comprising:
one or more inspection systems configured to acquire one or more sets of inspection data from at least a portion of at least one photovoltaic cell;
a computer control system communicatively coupled to the one or more inspection systems and configured to:
receive one or more inspection data sets acquired from the at least a portion of the at least one photovoltaic cell;
identify one or more interruption defects in one or more fingers of at least one electrode of the at least one photovoltaic cell utilizing the one or more inspection data sets;
determine one or more spatial parameters associated with at least one of the one or more identified interruption defects; and
generate an interruption criticality index value indicative of interruption-defect-induced efficiency loss of the at least one photovoltaic cell utilizing the determined one or more spatial parameters associated with the at least one of the one or more identified interruption defects of the at least one photovoltaic cell.

19. The system of claim 18, wherein the interruption criticality index generated by the computer control system is a length index.

20. The system of claim 18, wherein the interruption criticality index generated by the computer control system is a zone index.

21. The system of claim 18, wherein the interruption criticality index generated by the computer control system is a combined index, wherein the combined index includes a combination of a zone index and a length index.

22. The system of claim 18, wherein the interruption criticality index generated by the computer control system is an aggregated index, wherein the aggregated index includes a sum of the interruption criticality indexes of at least two or more of the identified interruption defects of the at least one photovoltaic cell.

23. The system of claim 18, wherein the interruption criticality index generated by the computer control system is a function of a design of the at least one photovoltaic cell.

24. A method for characterizing efficiency impact caused by one or more interruption defects of one or more photovoltaic cells, comprising:
receiving one or more inspection data sets acquired from the at least a portion of the at least one photovoltaic cell;
identifying one or more interruption defects in one or more fingers of at least one electrode of the at least one photovoltaic cell utilizing the one or more inspection data sets;
determining one or more spatial parameters associated with at least one of the one or more identified interruption defects; and
determining an interruption-defect-induced efficiency loss of the at least one photovoltaic cell based on the determined one or more spatial parameters associated with the at least one of the one or more identified interruption defects and the one or more floating finger portions of the one or more fingers created by two or more identified interruption defects.

25. A method for characterizing efficiency impact caused by one or more interruption defects of one or more photovoltaic cells, comprising:
receiving one or more inspection data sets acquired from the at least a portion of the at least one photovoltaic cell;
identifying one or more interruption defects in one or more fingers of at least one electrode of the at least one photovoltaic cell utilizing the one or more inspection data sets;
determining one or more spatial parameters associated with at least one of the one or more identified interruption defects; and
generating an interruption criticality index value indicative of interruption-defect-induced efficiency loss of the at least one photovoltaic cell utilizing the determined one or more spatial parameters associated with the at least one of the one or more identified interruption defects of the at least one photovoltaic cell.
